(19) United States
(12) Patent Application Publication
(10) Pub. No.: US 2006/0286742 A1
(43) Pub. Date: Dec. 21, 2006

(54) Method for fabrication of surface mounted metal foil chip resistors

(75) Inventor: Wood Mu-Yuan Chen, Taipei County (TW)

Correspondence Address: BACON & THOMAS, PLLC, 625 SLATERS LANE, FOURTH FLOOR, ALEXANDRIA, VA, 22314, US

(73) Assignee: Yageo Corporation, Hsin Tien (TW)

(21) Appl. No.: 11/156,523

(22) Filed: Jun. 21, 2005

(51) Int. Cl. H01L 21/8244; H01L 21/20

(52) U.S. Cl. 438/238; 438/382; 438/384; 438/385

(57) ABSTRACT

The present invention provides a method for fabricating metal foil chip resistors, comprising: providing an insulator substrate; forming a conductor layer pattern as a terminal electrode on said insulator substrate; adhering a metal foil having specific resistivity to said insulator substrate; applying the resistor wiring pattern upon said metal foil by employing the resist; and patterning the resistor wiring by a chemical etching method. Then said metal foil resistor layer is cut or otherwise processed by employing a laser method or other similar methods, thus a predetermined resistance value is obtained. Subsequently, further steps are performed to finish the process of fabricating metal foil chip resistors.

### BACKGROUND OF THE INVENTION

1. Field of the Invention

The present invention relates generally to a method for fabricating metal foil chip resistors employed within microelectronic devices; more particularly, to a method for fabricating metal foil chip resistors of high precision with a simplified process.

2. Description of the Related Art

Common in the art of microelectronics fabrication is the use of metal foil resistors as passive electrical circuit elements and/or load bearing electrical circuit elements. Metal foil resistors may be employed in microelectronic products.

When employed within hybrid circuit microelectronics fabrications, metal foil resistors are typically formed through photolithographic patterning, through methods as are conventional in the art, of blanket layers of metal foil resistor materials which are formed upon insulator substrates, such as but not limited to glass insulator substrates and ceramic insulator substrates, portions of which insulator substrates are subsequently parted to form discrete metal foil chip resistors.

A conventional method of fabricating metal foil chip resistors comprises the following steps: (1) providing an insulator substrate, (2) affixing a metal foil to the surface of said substrate, (3) forming through a photolithographic method a photoresist film coated onto resistor element, (4) modifying through mechanical fabrication method onto resistive element to obtain the predetermined resistance, (5) applying the overacting as sealant, (6) separating the respective resistors, (7) soldering the resistor layer to the end termination, (8) packaging the case, (9) testing and screening, and (10) packing and shipping. In the above-mentioned processes, a few times of patterning and applying processes are involved, the complicated calibration and working are required, the soldering for bonding the resistor layer and the lead is required, and the overcoating and/or injection molding for packaging is also required. Thus the manufacturing time and cost are increased.

### SUMMARY OF THE INVENTION

In view of the above problems of prior arts, the present invention provides a method for fabricating metal foil chip resistors, where metal foil chip resistors of high precision can be fabricated by a simplified process.

One object of the present invention is to provide a method for fabricating metal foil chip resistors, where a series of discrete metal foil chip resistors are formed.

Another object of the present invention is to provide a method for fabricating metal foil chip resistors, where various photolithographic methods, materials and devices are avoided.

Another object of the present invention is to provide a method for fabricating metal foil chip resistors, where the soldering and injection molding apparatuses are not necessary.

Another object of the present invention is to provide a method for fabricating metal foil chip resistors, where the discrete metal foil chip resistors adapted to be easily separated are formed.

### BRIEF DESCRIPTION OF THE DRAWINGS

The technical content and features of the present invention will be described in a way of detailed illustration of the preferred embodiment, with reference to the following accompanying drawings:

FIG. 1 is a cross-sectional diagram illustrating a first step of a method for fabricating metal foil chip resistors according to an embodiment of the present invention;

FIG. 2 is a cross-sectional diagram illustrating a second step of the method for fabricating metal foil chip resistors according to an embodiment of the present invention;

FIG. 3 is a cross-sectional diagram illustrating a third step of the method for fabricating metal foil chip resistors according to an embodiment of the present invention;

FIG. 4 is a cross-sectional diagram illustrating a fourth step of the method for fabricating metal foil chip resistors according to an embodiment of the present invention;

FIG. 5 is a cross-sectional diagram illustrating a fifth step of the method for fabricating metal foil chip resistors according to an embodiment of the present invention;

FIG. 6 is a cross-sectional diagram illustrating a sixth step of the method for fabricating metal foil chip resistors according to an embodiment of the present invention;

FIG. 7 is a cross-sectional diagram illustrating a seventh step of the method for fabricating metal foil chip resistors according to an embodiment of the present invention;

FIG. 8 is a cross-sectional diagram illustrating an eighth step of the method for fabricating metal foil chip resistors according to an embodiment of the present invention;

FIG. 9 is a cross-sectional diagram illustrating a ninth step of the method for fabricating metal foil chip resistors according to an embodiment of the present invention;

FIG. 10 is a cross-sectional diagram illustrating a tenth step of the method for fabricating metal foil chip resistors according to an embodiment of the present invention;

FIG. 11 is a cross-sectional diagram illustrating a product formed according to the method for fabricating metal foil chip resistors.

### DESCRIPTION OF THE PREFERRED EMBODIMENT

A further explanation of a method for fabricating metal foil chip resistors according to an embodiment of the present invention is provided as follows, with reference to the accompanying drawings.

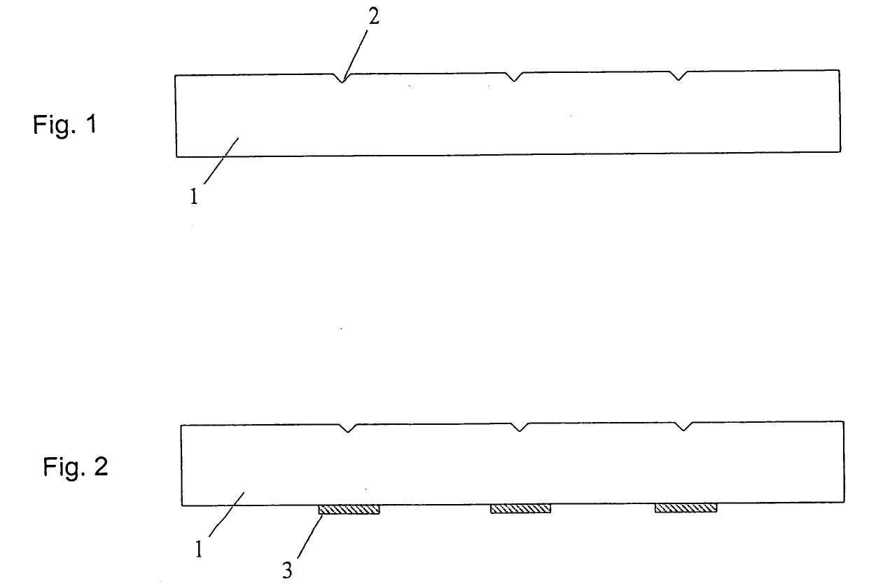

FIG. 1 is a cross-sectional diagram illustrating a first step of a method for fabricating metal foil chip resistors according to an embodiment of the present invention. Referring to FIG. 1, a substrate 1, formed by insulating material, is prepared as a process substrate of metal foil chip resistors.

A plurality of parallel and equally spaced notches 2 are formed upon the substrate 1, where the notches 2 are extending both horizontally and longitudinally. Thus the chessboard-like notches 2 are formed upon the upper surface of the substrate 1.

FIG. 2 is a cross-sectional diagram illustrating a second step of the method for fabricating metal foil chip resistors according to an embodiment of the present invention. As shown in FIG. 2, a series of bottom conductor lead (electrode) layers 3 are formed on the backside surface (opposite to the surface on which the notches 2 are formed) of the substrate 1. According to the method of the present invention, the series of bottom conductor lead (electrode) layers 3 are formed by a non-photolithographic application method (for example, screen printing method). The screen printing method is performed by printing a conductor ink selected from the group of conductor ink consisting of silver, silver alloy, gold, gold alloy, copper, copper alloy, palladium, palladium alloy, nickel, nickel alloy, etc. And then drying and firing are performed to thus form the series of bottom conductor lead (electrode) layers 3. The conductor ink is fired at a temperature from 800 to 900° C. (or lower) for a time period from 5 to 15 minutes.

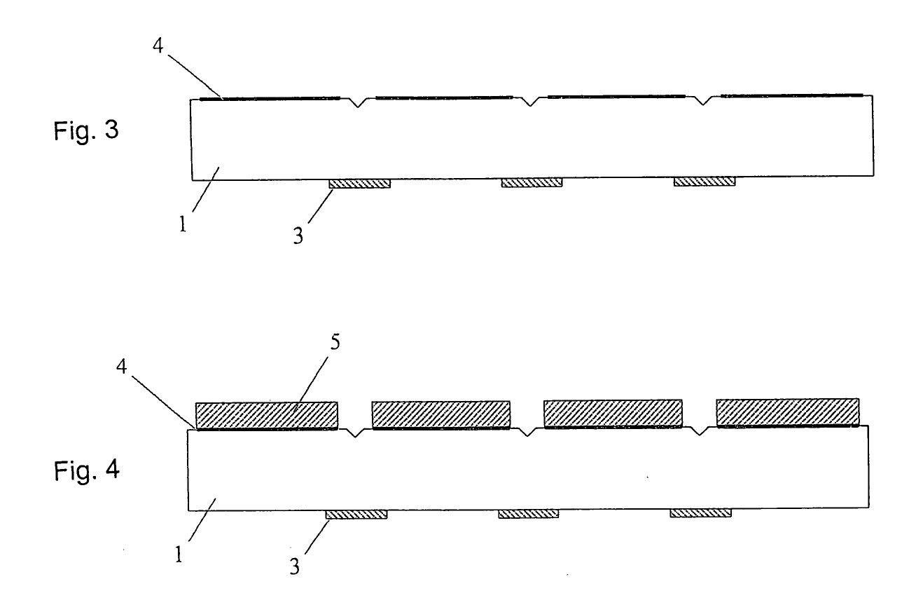

FIG. 3 is a cross-sectional diagram illustrating a third step of the method for fabricating metal foil chip resistors according to an embodiment of the present invention, where the adhesive is uniformly applied upon the upper surface of the substrate 1 by a non-photolithographic application method (for example, screen printing method).

FIG. 4 is a cross-sectional diagram illustrating a fourth step of the method for fabricating metal foil chip resistors according to an embodiment of the present invention. According to FIG. 4, a metal foil is adhered to the substrate 1 to thus form a metal foil resistor layer 5. Said metal foil resistor layer 5 is formed from any resistive material known in the art of metal foil resistor fabrication, for example, nickel-chromium alloy materials, nickel-chromium-aluminum alloy materials, manganese-copper alloy materials, nickel-chromium alloy materials, and higher order alloys of the forgoing resistive materials; and the thickness thereof is preferably between 0.05 and 0.2 centimeters, even thinner.

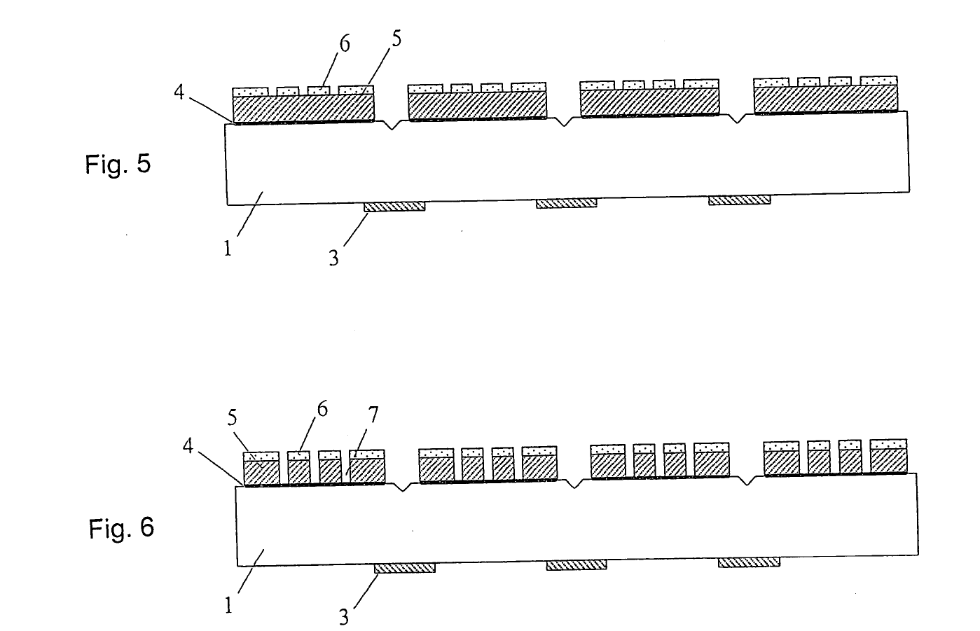

FIG. 5 is a cross-sectional diagram illustrating a fifth step of the method for fabricating metal foil chip resistors according to an embodiment of the present invention. According to FIG. 5, a pre-patterned resist mask 6 is applied over the metal foil resistor layer 5. The resist mask 6 is formed from non-metal materials as a web structure. The distance between the centers for each of the units comprising said web structure is equal to the distance between the center lines for each of the metal foil resistor layers 5, so that the resist mask is accurately put over the metal foil resistor layer 5.

FIG. 6 is a cross-sectional diagram illustrating a sixth step of the method for fabricating metal foil chip resistors according to an embodiment of the present invention. According to FIG. 6, the etch patterned element 7 is formed by etching with chemicals.

FIG. 7 is a cross-sectional diagram illustrating a seventh step of the method for fabricating metal foil chip resistors according to an embodiment of the present invention. According to FIG. 7, the resist mask 6 over the metal foil resistor layers 5 is removed by placing the substrate 1 into the alkaline solution since the resist mask 6 is not resistive to the alkaline solution.

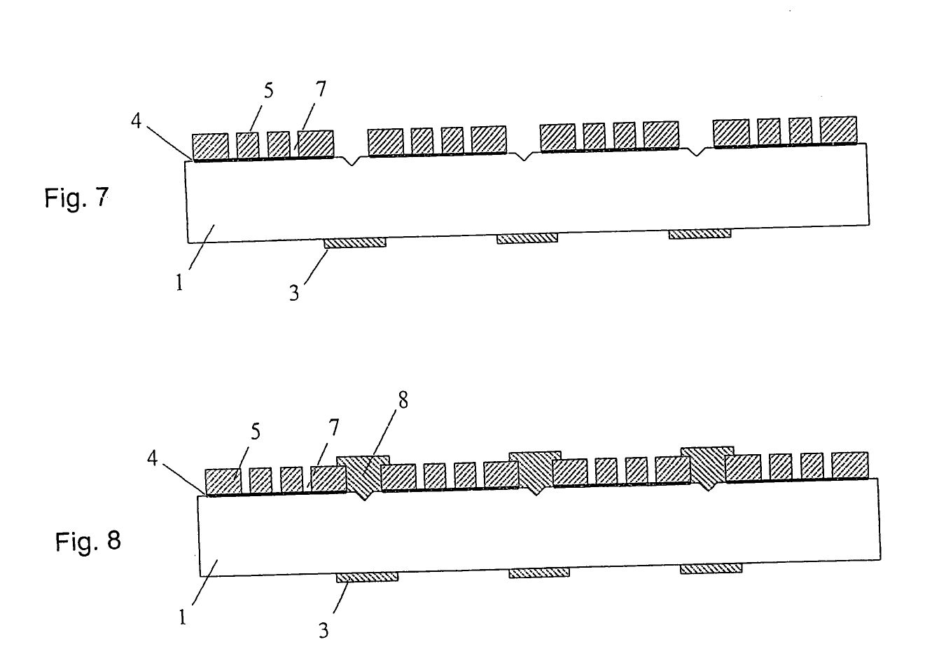

FIG. 8 is a cross-sectional diagram illustrating an eighth step of the method for fabricating metal foil chip resistors according to an embodiment of the present invention. As shown in FIG. 8, a series of upper conductor lead (electrode) layers 8 are formed. According to the method of the present invention, the series of upper conductor lead (electrode) layers 8 are formed by a non-photolithographic application method (for example, screen printing method). The screen printing method is performed by printing a conductor ink selected from the group of conductor ink consisting of silver, silver alloy, gold, gold alloy, copper, copper alloy, palladium, palladium alloy, nickel, nickel alloy, etc. And then drying and firing are performed to thus form the series of upper conductor lead (electrode) layers 8. The conductor ink is fired at a temperature from 200 to 300° C. (or lower) for a time period from 5 to 15 minutes.

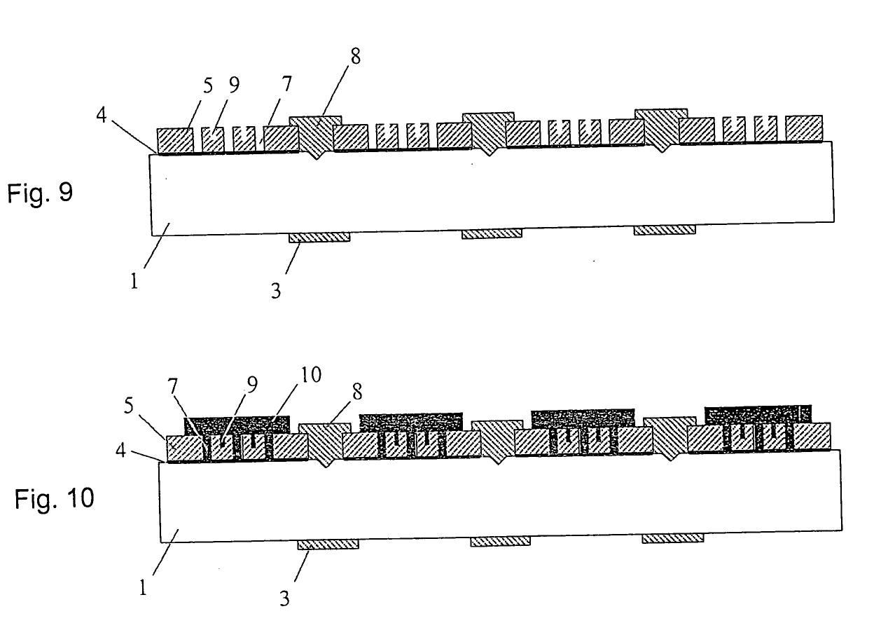

FIG. 9 is a cross-sectional diagram illustrating a ninth step of the method for fabricating metal foil chip resistors according to an embodiment of the present invention. The ninth step is performed by a non-photolithographic etching method, which is preferably a a non-photolithographic energy beam etching method employing an energy beam such as but not limited to a laser beam, a focused ion beam or a focused electron beam. In particular, the non-photolithographic energy beam etching method employs nickel-chromium-aluminum alloy resistive materials, manganese-copper alloy resistive materials, nickel-copper alloy resistive materials. Preferably, a laser beam at a wavelength of from 236 to 1064 nanometers and an energy density of from about 0.05 to about 10 watts per square centimeter projected beam size is employed. When patterning the metal foil resistor layers 5 to form the series of patterned metal foil resistor layers, the width of the laser beam is preferably from about 10 to about 100 microns; while when trimming the series of patterned metal foil resistor layers to form the series of trimmed patterned metal foil resistor layers 5, the diameter of the laser beam is preferably from about 2 to about 100 microns in width.

FIG. 10 is a cross-sectional diagram illustrating a tenth step of the method for fabricating metal foil chip resistors according to an embodiment of the present invention. Shown in FIG. 10 is a schematic cross-sectional diagram of the insulator substrate 1 otherwise equivalent to the insulator substrate 1 whose schematic cross-sectional diagram is illustrated in FIG. 9 but upon whose surface is formed a series of patterned protective layers 10 corresponding with portions of the trimmed patterned metal foil resistor layers 5 to encapsulate those portions of the trimmed patterned thin film resistor layers 5. The patterned protective layers 10 may be formed from any of several sealant materials as are commonly employed in the art of metal foil chip resistor fabrication, including but not limited to epoxy sealants, urethane sealants and silicone sealants. Within the preferred embodiment of the method of the present invention, the patterned protective layers 10 are, similarly with the series of patterned upper conductor lead (electrode) layers 8 and the series of patterned of bottom conductor lead (electrode) layers 3, formed through a non-photolithographic printing method, preferably a non-photolithographic screen printing method. Preferably the patterned protective layers 10 are formed of a sealant material not susceptible to degradation when exposed to subsequent processing steps, for example, code printing. More preferably, the patterned protective layers 10 are formed of an epoxy sealant material screen printed upon the insulator substrate 1 to provide the patterned protective layers 10 each of a thickness of from about 20 to about 40 microns.

Then, a process of parting the metal foil resistor units is performed. Due to the presence of the notches 2 arranged both horizontally and longitudinally, the substrate 1 may be parted to form the substrate strips through physical fracture without cutting the substrate 1. Preferably, the physical fracture is effectuated through fixturing the substrate 1 over a roller of radius about 2 to about 8 centimeters and sufficiently pressuring the insulator substrate 1 over the roller to induce the physical fracture. Other methods may, however, also be employed in parting the substrate 1 into the substrate strips.

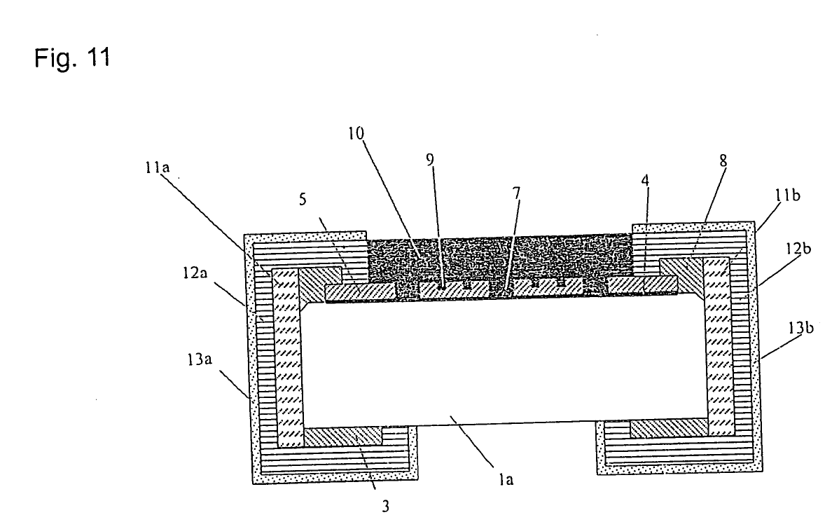

FIG. 11 is a cross-sectional diagram illustrating a product formed according to the method for fabricating metal foil chip resistors. Shown in FIG. 11 is a schematic cross-sectional diagram of a unit 1a formed by parting the substrate strip as illustrated in FIG. 10 again through physical fracture, but upon each edge of a pair of opposite edges of the unit 1a is formed a series of three conductor layers. The two series of three conductor layers so formed includes: (1) a pair of patterned terminal bridging conductor lead layers 11a and 11b formed bridging to the corresponding patterned upper conductor lead (electrode) layers 8 and the corresponding patterned of bottom conductor lead (electrode) layers 3; (2) a pair of patterned terminal medium conductor layers 12a and 12b formed upon the corresponding patterned terminal bridging conductor lead layers 11a and 11b; and (3) a pair of patterned terminal solder layers 13a and 13b formed upon the pair of patterned terminal medium conductor layers 12a and 12b. Each of the foregoing conductor layers within the foregoing two series of three conductor layers may be formed through any of several methods and materials as are known in the art of metal foil chip resistor fabrication.

Although the patterned terminal medium conductor layers 12a and 12b, and the patterned terminal solder layers 13a and 13b may be formed through any of several materials through which patterned terminal medium conductor layers and patterned terminal solder layers are formed when fabricating discrete metal foil chip resistors, for the preferred embodiment of the method of the present invention, the patterned terminal medium conductor layers 12a and 12b are preferably formed of a nickel or a nickel alloy conductor material, while the patterned terminal solder layers 13a and 13b are preferably formed of a lead or lead-tin alloy solder material. The use of nickel or nickel alloy materials when forming the patterned terminal medium conductor layers 12a and 12b and the use of lead or lead-tin alloy solder materials when forming the patterned terminal solder layers 13a and 13b typically provides a discrete metal foil resistor chip with optimal corrosion resistance and bondability within hybrid circuit microelectronics fabrications. Similarly, although the patterned terminal medium conductor layers 12a and 12b, and the patterned terminal solder layers 13a and 13b, may be formed through any of several methods through which patterned terminal medium conductor layers and patterned terminal solder layers may be formed within discrete metal foil resistor chip fabrication, the patterned terminal medium conductor layers 12a and 12b, and the patterned terminal solder layers 13a and 13b, are each preferably formed through a plating method in order to most efficiently provide the patterned terminal medium conductor layers 12a and 12b, and patterned terminal solder layers 13a and 13b, with the optimal corrosion resistance and bondability within hybrid circuit microelectronics fabrications.

Although not specifically illustrated within FIG. 11, the substrate strip is typically subsequently parted to form from the substrate strip a series of discrete substrate chips having formed thereupon a series of discrete metal foil resistors in accord with the schematic cross-sectional diagram of FIG. 11, thus forming a series of discrete metal foil resistor chips. The discrete metal foil resistor chips 1a are preferably parted from the substrate strip through a method analogous to the method employed in parting the substrate strip from the insulator substrate 1. In particular, the substrate strip is preferably parted to form the metal foil resistor chips 1a through physical fracture of the substrate strip along the remaining horizontal notches, without cutting the substrate strip.

Although not specifically illustrated by the schematic cross-sectional diagram of FIG. 11, the substrate strip may be parted to form the discrete metal foil resistor chips comprised of the discrete insulator substrate chips having formed thereupon the discrete metal foil chip resistors either prior to or after forming the pair of patterned terminal medium conductor layers 12a and 12b and the pair of patterned terminal solder layers 13a and 13b upon the insulator substrate chips 1a. Within the preferred embodiment of the method of the present invention, the insulator substrate strip is preferably parted to form a series of insulator substrate chips having formed thereupon the series of metal foil chip resistors before forming through the plating methods the patterned terminal medium conductor layers 12a and 12b and the patterned terminal solder layers 13a and 13b.

As is understood by a person skilled in the art, the preferred embodiment of the method of the present invention is illustrative of the method of the present invention rather than limiting of the method of the present invention. Revisions and modifications may be made to materials, structures and dimensions through which is formed the discrete thin film resistor chip through the preferred embodiment of the method of the present invention while still forming a thin film resistor in accord with the method of the present invention, as defined by the accompanying claims.

1. A method for forming a metal foil chip resistor, comprising:
providing an insulator substrate;
adhering a metal foil of alloy resistive material to said insulator substrate;
applying a pre-patterned resist mask upon said metal foil;
forming said metal foil applied with said resist mask as a resistor layer;
removing said resist mask from the surface of said metal foil, thereby patterning said resistor layer;
removing through a non-photolithographic application method and energy beam trimming method a portion of said patterned resistor layer so that said resistor layer has a predetermined resistance value.

2. The method of claim 1, wherein the insulator substrate is selected from the group of insulator substrates consisting of glass insulator substrates, ceramic insulator substrates and epoxy resin substrates.

3. The method of claim 1, wherein said metal foil resistor layer is formed from a resistive material selected from the group of resistive materials consisting of tantalum-chromium alloy resistive materials, nickel-chromium alloy resistive materials, nickel-chromium-aluminum alloy resistive materials, manganese-copper alloy resistive materials, nickel-copper alloy resistive materials and higher order alloys of the foregoing resistive materials.

4. The method of claim 1, wherein the non-photolithographic energy beam trimming method is an etching method selected from the group consisting of laser beam trimming methods, focused ion beam trimming methods and focused electron beam trimming methods.
